(19) United States
(12) Patent Application Publication
(10) Pub. No.: US 2026/0246250 A1
(43) Pub. Date: Aug. 20, 2026

(54) ELECTRICAL JUNCTION BOX AND METHOD FOR PRODUCING SAME

(71) Applicant: Panasonic Intellectual Property Management Co., Ltd., Osaka (JP)

(72) Inventors: Yusuke MAEDA, Hyogo (JP); Hiroyuki MIHARA, Hyogo (JP); Masashi KANAYAMA, Osaka (JP); Hideki WATANABE, Osaka (JP); Toshiki NAKASHO, Osaka (JP)

(73) Assignee: Panasonic Intellectual Property Management Co., Ltd., Osaka (JP)

(21) Appl. No.: 19/159,429

(22) PCT Filed: Mar. 5, 2024
(86) PCT No.: PCT/JP2024/008251

§ 371 Date: Aug. 25, 2025

(30) Foreign Application Priority Data
Mar. 27, 2023 (JP) 2023-050633

(51) Int. Cl. H02G 3/08; B60L 3/04; H01H 45/04; H02G 3/03; H02G 3/16; H02G 5/08; H02G 5/10

(52) U.S. Cl. CPC H02G 3/081; B60L 3/04; H01H 45/04; H02G 3/03; H02G 3/16; H02G 5/08; H02G 5/10

(57) ABSTRACT

A battery disconnect unit as one example of an electrical junction box includes a case, the case being a resin case and being electrically insulating, a relay disposed in the case a bus bar connected to a terminal of the relay and fixed to the case by insert molding, a metal plate, and a heat conducting sheet disposed between the case and the metal plate.

### TECHNICAL FIELD

The present disclosure relates to an electrical junction box such as a battery disconnect unit and a method for producing the same.

### BACKGROUND ART

Electric vehicles such as hybrid electric vehicles or battery electric vehicles include a battery for power supply and an electrical junction box for connecting the battery to a variety of electrical devices (Patent Literature (PTL) 1).

As such an electrical junction box, a battery disconnect unit (BDU) is known. The battery disconnect unit includes a relay that disconnects or feed electricity output from the battery. For example, the battery disconnect unit includes a case including a resin, a relay accommodated in the case, and a bus bar connected to a terminal of the relay.

### CITATION LIST

### Patent Literature

### [PTL 1] Japanese Unexamined Patent Application Publication No. 2005-210804

### SUMMARY OF INVENTION

### Technical Problem

However, such traditional battery disconnect units have insufficient strength in connection between the terminal (fixed terminal) of the relay and the bus bar.

In battery disconnect units, in which heat generates in the relay which is a power device, it is difficult to sufficiently dissipate heat generated in the relay due to a long distance from the terminal of the relay to an external heat dissipating device. In particular, when electric vehicles rapidly accelerate in a short time to drastically discharge a current from the battery, the temperature of the relay increases.

In addition, in battery disconnect units, it is important to ensure insulation because a large current flows in the bus bar, while depending on the insulation structure, the insulation structure may inhibit dissipation of heat generated in the relay.

Thus, such traditional battery disconnect units are difficult to satisfy connection strength between the relay and the bus bar, heat dissipating properties, and insulation properties at the same time.

The present disclosure has been made to solve such a problem. An object of the present invention is to provide an electrical junction box which can satisfy connection strength between the relay and the bus bar, heat dissipating properties, and insulation properties at the same time, and a method for producing the same.

### Solution to Problem

To solve the above object, one aspect of the electrical junction box according to the present disclosure includes a case, the case being a resin case and being electrically insulating; a relay disposed in the case; a bus bar connected to a terminal of the relay and fixed to the case by insert molding; a metal plate; and a heat conducting sheet disposed between the case and the metal plate.

One aspect of the method for producing an electrical junction box according to the present disclosure includes disposing a relay in a case to which a bus bar is fixed; disposing a relay cover above the relay disposed in the case; fixing the relay cover to the case in a state where the relay cover is pressed against the case; and fixing a terminal of the relay and the bus bar with a screw after the fixing of the relay cover to the case.

### Advantageous Effects of Invention

The present disclosure can satisfy connection strength between the relay and the bus bar, heat dissipating properties, and insulation properties at the same time.

### BRIEF DESCRIPTION OF DRAWINGS

FIG. 1 is a block diagram of a driving system according to an embodiment.

FIG. 2 is a perspective view of a battery disconnect unit according to the embodiment.

FIG. 3 is an exploded perspective view of the battery disconnect unit according to the embodiment.

FIG. 4 is a cross-sectional view of the battery disconnect unit according to the embodiment.

FIG. 5 is an enlarged cross-sectional view of an essential portion of the battery disconnect unit according to the embodiment.

FIG. 6 is a diagram for illustrating the method for producing a battery disconnect unit according to the embodiment.

FIG. 7 is a diagram illustrating the configuration of a battery disconnect unit according to Comparative Example.

### DESCRIPTION OF EMBODIMENTS

Hereinafter, an embodiment according to the present disclosure will be described with reference to the drawings. The embodiment described below illustrates one specific examples of the present disclosure. Accordingly, numeric values, components, arrangement positions of components and connection forms thereof, steps, and order of steps shown in the embodiment below are exemplary, and should not be construed as limitations to the present disclosure. Thus, among the components in the embodiment below, the components not described in independent claims are described as optional components.

The drawings are schematic views, and are not always strict illustrations. In the drawings, identical reference signs are given to substantially identical configurations, and duplications of descriptions will be omitted or simplified. In this specification, terms “above” and “below” do not always indicate the upper direction (vertically upper direction) and lower direction (vertically lower direction) in absolute spatial recognition.

### Embodiment

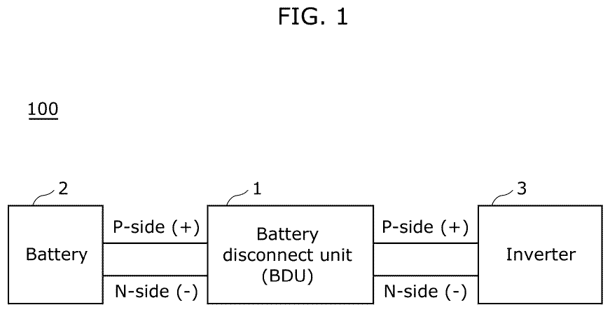

First, driving system 100 will be described as one example of a system included in battery disconnect unit 1 according to an embodiment. FIG. 1 is a block diagram of driving system 100 according to the embodiment.

As illustrated in FIG. 1, driving system 100 includes battery disconnect unit 1, battery 2, and inverter 3.

Battery disconnect unit 1 is one example of an electrical junction box for connecting battery 2 to a variety of electrical devices. For example, battery disconnect unit 1 is connected between battery 2 and inverter 3 to disconnect DC electricity output from battery 2 or feed the electricity to inverter 3. In other words, battery disconnect unit 1 can switch between the electricity feed state to feed electricity to inverter 3 and the electricity disconnect state to disconnect electricity to inverter 3.

Although not illustrated, battery disconnect unit 1 may be connected not only to inverter 3 but also to a rapid charge circuit. In this case, battery disconnect unit 1 can switch inverter 3 and the rapid charge circuit as the output destination of the DC electricity output from battery 2. Battery disconnect unit 1 can also switch between the electricity feed state to feed electricity to the rapid charge circuit and the electricity disconnect state to disconnect electricity to the rapid charge circuit. As another configuration, the rapid charge circuit can be mounted on battery disconnect unit 1.

Battery 2 is a power storage device such as a secondary battery. Battery 2 outputs DC electricity. Thus, battery 2 connected to battery disconnect unit 1 feeds DC electricity to battery disconnect unit 1. For example, battery 2 is a lithium ion secondary battery, but not limited thereto.

Inverter 3 is an AC/DC converter, which converts DC electricity fed from battery disconnect unit 1 to AC electricity. Although not illustrated, for example, inverter 3 is connected to a motor, and the motor connected to inverter 3 is driven by AC electricity output from inverter 3.

Driving system 100 having such a configuration is provided in an electric vehicle such as a hybrid electric vehicle or a battery electric vehicle. In other words, battery disconnect unit 1 together with battery 2 is provided in an electric vehicle. In this case, as driving energy for running the electric vehicle, the DC electricity output from battery 2 is fed through battery disconnect unit 1 to inverter 3, and is converted to AC electricity. The AC electricity output from inverter 3 is fed to a motor which drives to rotate the wheels of the vehicle.

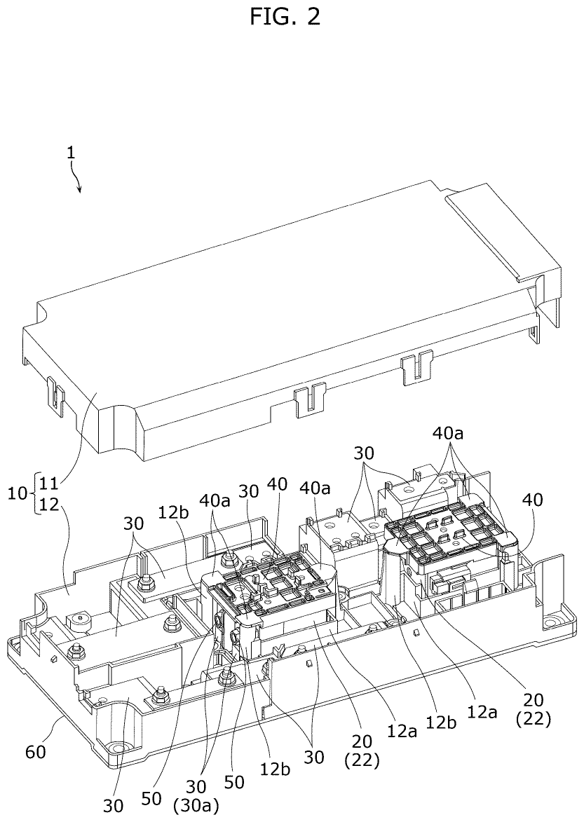

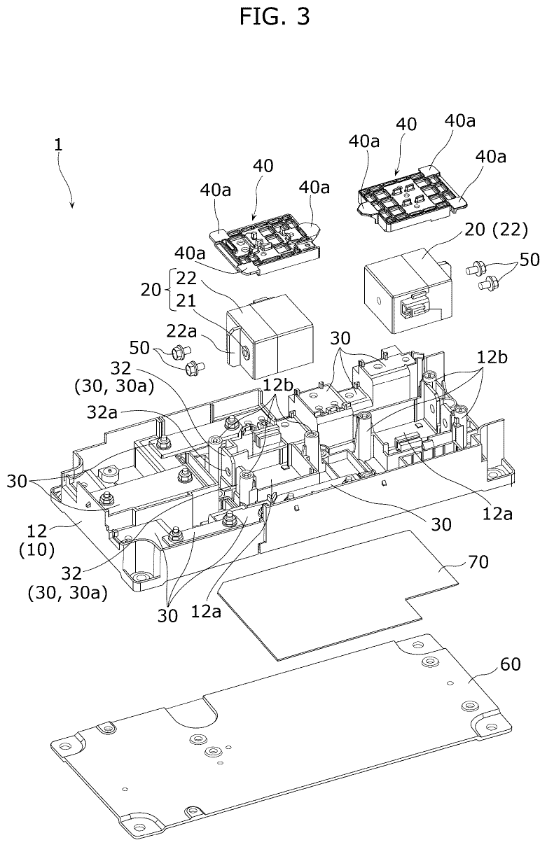

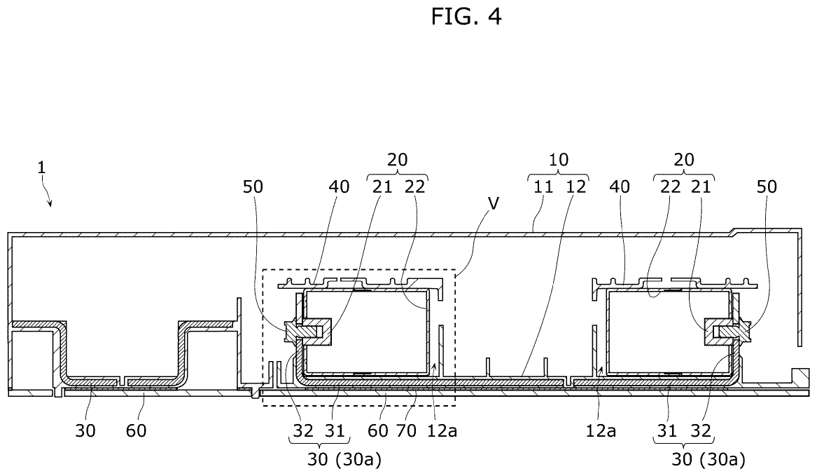

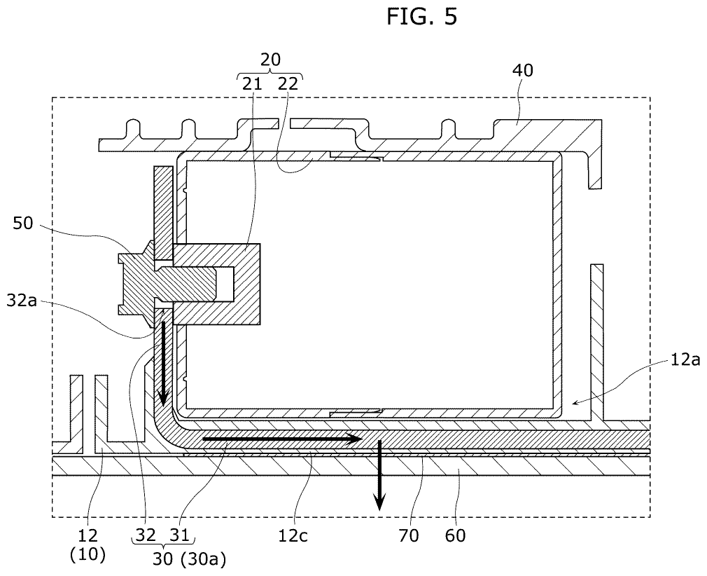

Next, the structure of battery disconnect unit 1 according to the embodiment will be described with reference to FIGS. 2 to 5. FIG. 2 is a perspective view of battery disconnect unit 1 according to the embodiment. FIG. 2 illustrates a state where upper case 11 is removed. FIG. 3 is an exploded perspective view of battery disconnect unit 1 according to the embodiment. In FIG. 3, upper case 11 is omitted. FIG. 4 is a cross-sectional view of battery disconnect unit 1 according to the embodiment. FIG. 4 basically illustrates only a portion shown in a cross-section. FIG. 5 is an enlarged cross-sectional view of an essential portion of battery disconnect unit 1 according to the embodiment. Specifically, FIG. 5 is an enlarged cross-sectional view of region V represented by the dashed line in FIG. 4.

As illustrated in FIGS. 2 to 5, battery disconnect unit 1 includes case 10, relay 20, bus bar 30, relay cover 40, screw 50, metal plate 60, and heat conducting sheet 70.

Besides relay 20, battery disconnect unit 1 may include other electronic components, such as a fuse such as a pyrofuse (pyrotechnic disconnector), a current sensor such as a Hall sensor, and a resistor such as a shunt resistor.

Case 10 is a housing that accommodates parts. In the present embodiment, case 10 accommodates relay 20, bus bar 30, and relay cover 40. Case 10 accommodates parts other than these. Case 10 is an outer member of battery disconnect unit 1.

As illustrated in FIG. 2, case 10 includes upper case 11 as a first cover and lower case 12 as a second cover. Upper case 11 is combined with lower case 12 to cover lower case 12. The parts accommodated in case 10 are mainly arranged in lower case 12. Relays 20 and bus bars 30 are arranged in lower case 12.

As illustrated in FIGS. 2 to 4, in the present embodiment, lower case 12 includes relay accommodation portion 12a, and relay 20 is disposed in relay accommodation portion 12a. As illustrated in FIGS. 3 and 4, relay accommodation portion 12a is a recess disposed in part of lower case 12, and relay housing 22 of relay 20 is accommodated in the recess. Specifically, as illustrated in FIG. 4, the rear surface of relay housing 22 is in surface contact with the bottom surface of relay accommodation portion 12a as the recess.

As illustrated in FIGS. 2 and 3, lower case 12 includes support 12b that supports relay cover 40. Relay cover 40 is fixed to support 12b. Support 12b is part of lower case 12, and is formed to project toward upper case 11. As illustrated in FIG. 3, specifically, support 12b is formed in a cylindrical shape. A plurality of supports 12b are disposed in one relay cover 40. In the present embodiment, three supports 12b are arranged in one relay cover 40. Three supports 12b are arranged near relay accommodation portion 12a. Specifically, three supports 12b are arranged in a triangular layout to surround relay accommodation portion 12a. In the present embodiment, two relay covers 40 are arranged, and thus, lower case 12 incudes six supports 12b.

Case 10 illustrated in FIGS. 2 to 4 includes bus bars 30 fixed thereto. Although details will be described later, a plurality of bus bars 30 include bus bars 30 fixed to case 10 by insert molding. In other words, case 10 is a module case to which bus bars 30 are preliminarily fixed by insert molding. Specifically, bus bars 30 are fixed to lower case 12 by insert molding. Lower case 12 also includes nuts fixed thereto by insert molding, screws being inserted through the nuts when bus bars 30 are retrofitted to lower case 12. Thus, some of bus bars 30 and nuts are integrally formed in lower case 12 by insert molding.

Case 10 is a resin molded article including a resin material. Case 10 includes an insulative material. In the present embodiment, case 10 includes a resin material that is electrically insulating. Accordingly, case 10 is a housing being a resin housing and being electrically insulating. In other words, upper case 11 and lower case 12 constituting case 10 are each a resin molded article that is electrically insulating.

As the resin material for forming case 10, an alloy material of polyphenylene sulfide (PPS), polybutylene terephthalate (PBT), or polyphenylene ether (PPE) with nylon can be used, for example, in consideration of the heat-resistant temperature and strength. Upper case 11 and lower case 12 may include the same resin material, or may include different resin materials.

Relay 20 accommodated in case 10 is an electronic component having a function to turn on/off electrical conduction. Specifically, in FIG. 1, relay 20 has a function to switch disconnection and feed of DC electricity to inverter 3, the DC electricity being fed from battery 2 to battery disconnect unit 1. Relay 20 is a mechanical relay (contact relay). In the present embodiment, relay 20 to be used can also be a relay of another type (as one example, a semiconductor relay, contactless relay). More preferably, relay 20 is a mechanical relay to ensure disconnection and feed of a large current from a battery having a large capacity that is provided in an electric vehicle such as a hybrid electric vehicle or a battery electric vehicle.

As illustrated in FIGS. 2 to 5, each relay 20 includes a pair of terminals 21, and relay housing 22 having insulation to which the pair of terminals 21 are fixed. The pair of terminals 21 are fixed terminals. The pair of terminals 21 are external connection terminals connected to an external member. Specifically, the pair of terminals 21 are connected to bus bars 30, respectively. The pair of terminals 21 are metal terminals including a metal material. The pair of terminals 21 are electrically separated from each other.

Although not illustrated, each relay 20 includes a movable contact that is brought into contact with or spaced from one of the pair of terminals 21 which are fixed terminals. Relay 20 can disconnect or feed the current by movement of the movable contact to contact with the fixed terminal or space therefrom.

Relay housing 22 is a resin housing including a resin material that is electrically insulating, for example. As one example, relay housing 22 is a cuboid having six surfaces (top surface, bottom surface, four lateral surfaces). The movable contact is accommodated in relay housing 22.

As illustrated in FIGS. 2 and 3, each relay 20 further includes insulating plate 22a located between terminals 21. Insulating plate 22a is an insulating wall separating the pair of terminals 21. Specifically, insulating plate 22a is part of relay housing 22, and erects from the surface of relay housing 22 on which terminals 21 are arranged.

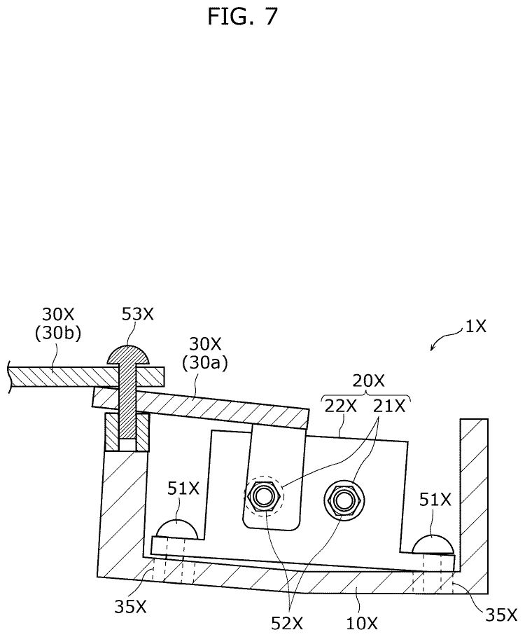

In the present embodiment, the lateral surfaces of relay housing 22 include no attachment (collar) for fixing relay housing 22 to case 10 with a screw. In other words, the lateral surfaces of relay housing 22 include no attachment projecting from the lateral surfaces of relay housing 22 and including a screw hole (attachment projecting from lateral surfaces of relay housing 22X illustrated in FIG. 7 described later).

As illustrated in FIGS. 2 and 4, relays 20 are disposed in case 10. In the present embodiment, relays 20 are disposed in lower case 12. Specifically, relay housing 22 of each relay 20 is accommodated in relay accommodation portion 12a disposed in lower case 12. In this case, relay housing 22 is accommodated sideways in relay accommodation portion 12a of lower case 12, and terminals 21 of each relay 20 are arranged on a lateral surface of relay housing 22. In other words, as illustrated in FIG. 2, relay 20 is disposed to align terminals 21 laterally, and terminals 21 face a lateral direction but not in the upper direction (upper case 11 side). Thereby, insulating plate 22a located between the pair of terminals 21 is also located on the lateral surface of relay housing 22.

Relays 20 are fixed to case 10. In the present embodiment, relays 20 are fixed to lower case 12. In this case, relays 20 are not directly fixed to lower case 12, but are fixed to lower case 12 with bus bars 30 preliminarily fixed to lower case 12. Specifically, as illustrated in FIGS. 2 and 4, each relay 20 is fixed to bus bars 30 by fixing bus bars 30 (relay bus bars 30a) fixed to lower case 12 and terminals 21 of relay 20 with screws 50. Relay bus bars 30a are in surface contact with terminals 21 of relay 20.

At least one relay 20 is disposed in battery disconnect unit 1. In the present embodiment, battery disconnect unit 1 includes a plurality of relays 20. The plurality of relays 20 each include a first main relay on a P-side corresponding to a P-side electrode of battery 2 (see FIG. 1) and a second main relay on an N-side corresponding to an N-side electrode of battery 2 (see FIG. 1). Specifically, as illustrated in FIGS. 2 and 3, two relays 20, i.e., the first main relay on the P-side and the second main relay on the N-side are arranged in case 10. The plurality of relays 20 each may include a pre-charge relay. When battery disconnect unit 1 incudes a rapid charge circuit, the plurality of relays 20 each may include a first rapid charge relay on the P-side corresponding to the P-side electrode of battery 2 and a second rapid charge relay on the N-side corresponding to the N-side electrode of battery 2.

Bus bar 30 disposed in case 10 is a wiring member in which a current flows, and forms an electrical conduction path. Since bus bar 30 is a wiring member in which a current flows, bus bar 30 includes a conductive material. Bus bar 30 also functions as a heat dissipating member (heat sink) for dissipating heat generated in heat generating components. For example, bus bar 30 dissipates heat generated in relay 20 which is one of the heat generating components. Thus, bus bar 30 preferably includes a metal material such as copper (Cu) or aluminum (Al) in consideration of electrical conductivity and thermal conductivity.

In the present embodiment, because a large current flows in bus bar 30, bus bar 30 has a relatively large thickness. Thus, bus bar 30 is a metal rigid body having a large thickness and high strength. For example, when battery disconnect unit 1 is used in a battery electric vehicle, bus bar 30 has a thickness of preferably more than 2 mm, more preferably 3 mm or more. For this reason, bus bar 30 has a thickness to avoid deflection caused by screwing when bus bar 30 is fixed with screws.

In the present embodiment, bus bar 30 includes copper as one example of the metal material. Specifically, bus bar 30 includes a plate-like metal plate including pure copper or a copper alloy and having a predetermined thickness. Bus bar 30 is formed in a stereoscopic predetermined shape by punching a flat plate-like metal plate into a predetermined shape and bending the metal plate by press processing or the like. To be noted, bus bar 30 is not limited to the one including a plate-like metal plate, and may include a cast metal conductor formed by a casting method (including die casting) (including a case where the metal is an alloy), for example. In particular, when bus bar 30 includes a cast metal conductor, the metal material for forming bus bar 30 is not limited to copper, and another metal material such as aluminum may be used, for example.

Preferably, a plating film is formed on the surface of bus bar 30. This can reduce contact resistance. The plating film can be formed by performing plating processing on bus bar 30 as a surface treatment. The plating film is a Ni-Sn plating film including nickel and tin, for example, but not limited thereto.

At least one bus bar 30 is disposed in battery disconnect unit 1. As illustrated in FIGS. 2 and 3, in the present embodiment, a plurality of bus bars 30 are disposed in case 10. As illustrated in FIGS. 2 to 4, the plurality of bus bars 30 include relay bus bar 30a which is bus bar 30 connected to relay 20. In this case, relay bus bar 30a is connected to terminal 21 of relay 20. Specifically, as illustrated in FIGS. 2 and 4, relay bus bar 30a is fastened to terminal 21 of relay 20 with screw 50. As illustrated in FIGS. 2 and 3, because one relay 20 includes two terminals 21, one relay 20 is fixed to two relay bus bars 30a. Two relay bus bars 30a are arranged side by side.

The plurality of bus bars 30 include bus bars 30 connected to an electronic component other than relay 20, and connection bus bars 30 connected only to another bus bar 30 without being connected to any electronic components.

As illustrated in FIG. 4, each of two relay bus bars 30a connected to relay 20 includes first plate portion 31, and second plate portion 32 which erects from first plate portion 31. First plate portion 31 and second plate portion 32 are formed by bending the relay bus bar into an L shape. In other words, each relay bus bar 30a is formed to have an L-shaped portion. Relay bus bar 30a can be in any other shape.

The plurality of bus bars 30 are fixed to case 10. Specifically, the plurality of bus bars 30 are fixed to lower case 12 of case 10. In this case, the plurality of bus bars 30 include bus bars 30 directly fixed to case 10 by insert molding, and bus bars 30 fixed by screwing screws into nuts fixed to case 10 by insert molding. In other words, nuts through which screws are inserted when bus bars 30 are retrofitted to lower case 12 are fixed to lower case 12 by insert molding.

In the present embodiment, relay bus bar 30a connected at least to relay 20 is fixed to case 10 by insert molding. Specifically, relay bus bar 30a is fixed to lower case 12 of case 10 by insert molding. Thus, relay bus bar 30a is partially embedded in part of lower case 12. Specifically, as illustrated in FIGS. 4 and 5, part or all of first plate portion 31 of bus bar 30 as relay bus bar 30a is embedded in lower case 12. In the present embodiment, all of first plate portion 31 is embedded in lower case 12. Thereby, relay bus bar 30a can be tightly fixed to lower case 12. In the present embodiment, first plate portion 31 of relay bus bar 30a is located below relay accommodation portion 12a of lower case 12.

As illustrated in FIGS. 4 and 5, second plate portion 32 of bus bar 30 as relay bus bar 30a erects with respect to lower case 12. In other words, second plate portion 32 is exposed from lower case 12, and extends from lower case 12 toward the upper direction (upper case 11 side). The end of second plate portion 32 faces terminal 21 of relay 20. In other words, second plate portion 32 extends to at least the position of terminal 21 of relay 20.

As illustrated in FIGS. 2 and 4, terminal 21 of relay 20 and bus bar 30 are fixed with screw 50. In the present embodiment, terminal 21 of relay 20 and second plate portion 32 of bus bar 30 as relay bus bar 30a are fixed with screw 50. Specifically, as illustrated in FIGS. 3 and 4, the end of second plate portion 32 includes insertion hole 32a as a screw hole, and relay bus bar 30a and relay 20 can be fixed by inserting screw 50 into insertion hole 32a of second plate portion 32 and screwing it into terminal 21 of relay 20. Insertion hole 32a disposed in second plate portion 32 which erects in first plate portion 31 is opened toward a lateral side. Thus, the insertion direction of screw 50 is a direction parallel to the bottom surface of lower case 12. Screw 50 is one example of the fastening member, and is a bolt in the present embodiment. Screw 50 is not limited to a bolt.

As illustrated in FIGS. 2 to 5, relay cover 40 is a cover which covers relay 20. Specifically, as illustrated in FIGS. 2 and 4, relay cover 40 is disposed to cover relay 20 disposed in relay accommodation portion 12a of lower case 12. In the present embodiment, relay cover 40 covers relay 20 to cover entire relay housing 22 of relay 20 in top surface view and to expose the lateral surfaces of relay housing 22 of relay 20 in a lateral surface view. Thus, terminals 21 of relay 20 are not covered by relay cover 40 in the insertion direction of screw 50.

Relay cover 40 presses relay 20 against case 10. Specifically, relay cover 40 presses relay housing 22 of relay 20 disposed in lower case 12 against lower case 12. As illustrated in FIG. 2, because two relays 20 are arranged in lower case 12 in the present embodiment, two relay covers 40 are arranged in lower case 12.

As illustrated in FIG. 2, relay cover 40 is disposed on the top portion of support 12b disposed in lower case 12, and relay cover 40 is supported by support 12b. In the present embodiment, because three supports 12b are arranged in one relay 20, relay cover 40 is supported by three supports 12b at three points.

Relay cover 40 disposed on support 12b is fixed to support 12b via attachment 40a. Relay cover 40 includes attachment 40a as a site attached to support 12b. Attachment 40a is disposed in a position corresponding to each support 12b in relay cover 40. As illustrated in FIGS. 2 and 3, because three supports 12b are arranged in lower case 12 in the present embodiment, three attachments 40a are arranged in one relay cover 40. Three attachments 40a are arranged in an outer circumferential portion of relay cover 40.

Relay cover 40 includes a plurality of protrusions formed on the top surface thereof. Since by arranging such protrusions in relay cover 40, wirings (not illustrated) extending inside case 10, such as a lead wire or a harness, can be fixed by hanging on or clamping with the protrusions, the wirings can be easily accommodated inside case 10.

Relay cover 40 is a resin molded article including a resin material that is electrically insulating. As the resin material for forming relay cover 40, as in case 10, an alloy material of PPS, PBT, or PPE with nylon can be used, for example, in consideration of the heat-resistant temperature and strength. Relay cover 40 and case 10 may include the same resin material, and may include different resin materials.

Relay cover 40 and case 10 are bonded. Specifically, attachment 40a of relay cover 40 is bonded to support 12b of lower case 12. In the present embodiment, attachment 40a of relay cover 40 is bonded to support 12b of lower case 12 by ultrasonic welding, thermal welding, or laser welding. In this case, attachment 40a of relay cover 40 is bonded to support 12b of lower case 12 by melting the resin forming relay cover 40 and the resin forming lower case 12.

When relay cover 40 and lower case 12 are bonded by ultrasonic welding, relay cover 40 and lower case 12 preferably include the same resin material. In this case, relay cover 40 and lower case 12 preferably include a resin material which is an alloy material of PPE with nylon, for example. When relay cover 40 is bonded to lower case 12 by thermal welding, relay cover 40 and lower case 12 may include different resin materials, or may include the same resin material.

Metal plate 60 is a metal plate including a metal material. For example, metal plate 60 is an aluminum plate including a metal material containing aluminum as the main component. Metal plate 60 is a flat plate-like metal plate. Metal plate 60 may include a metal material other than aluminum.

As illustrated in FIGS. 4 and 5, metal plate 60 is disposed below case 10. In other words, case 10 is disposed above metal plate 60. Specifically, lower case 12 of case 10 is disposed above metal plate 60. Metal plate 60 is disposed to cover the entire bottom surface of lower case 12. Metal plate 60 is fixed to lower case 12 with screws. Metal plate 60 with case 10 constitutes an outer member of battery disconnect unit 1. Specifically, metal plate 60 is a bottom plate of battery disconnect unit 1, and the bottom surface of metal plate 60 (surface opposite the surface facing heat conducting sheet 70) is an exposed surface. Thereby, heat which conducts to bus bar 30 and heat which generates in bus bar 30 conduct to metal plate 60, so that heat which conducts to bus bar 30 and heat which generates in bus bar 30 can be efficiently dissipated to the outside.

In particular, in the present embodiment, as described above, a plurality of bus bars 30 are embedded in and fixed to lower case 12 by insert molding. For this reason, metal plate 60 is close to the plurality of bus bars 30 embedded in lower case 12. Thereby, heat which conducts to bus bars 30 embedded in lower case 12 and heat which generates in bus bars 30 can be efficiently conducted to metal plate 60. For example, heat of relay 20 which conducts to bus bar 30 connected to relay 20 (relay bus bar 30a) can be efficiently conducted to metal plate 60. Accordingly, heat of relay 20 can be efficiently dissipated.

Preferably, the thermal conductivity of metal plate 60 is higher than that of heat conducting sheet 70. Preferably, the thickness of metal plate 60 is larger than that of heat conducting sheet 70. Thereby, heat which conducts to bus bars 30 and heat which generates in bus bars 30 can be efficiently conducted to metal plate 60 through heat conducting sheet 70. In the present embodiment, the thickness of metal plate 60 is 4 mm.

Metal plate 60 is in an electrically floating state (floating state). In other words, no voltage is applied to metal plate 60, and the current flowing in bus bar 30 does not flow in metal plate 60. For this reason, metal plate 60 serving as an outer member is preferably insulated and separated from bus bar 30.

As illustrated in FIGS. 4 and 5, heat conducting sheet 70 (thermal sheet) is disposed between lower case 12 and metal plate 60. Specifically, heat conducting sheet 70 is interposed between lower case 12 of case 10 and metal plate 60. Heat conducting sheet 70 is sandwiched between lower case 12 and metal plate 60.

In the present embodiment, heat conducting sheet 70 is in contact with case 10 and metal plate 60. Specifically, heat conducting sheet 70 is in close contact with the bottom surface (resin surface) of lower case 12 of case 10 and the top surface (metal surface) of metal plate 60.

Heat conducting sheet 70 conducts heat which conducts to bus bars 30 fixed to case 10 and heat which generates in bus bars 30 to metal plate 60. Thus, heat conducting sheet 70 preferably includes a material having high thermal conductivity. As one example, the thermal conductivity of heat conducting sheet 70 is 1 W/m·K or more, but should not be limited thereto.

Heat conducting sheet 70 preferably includes an insulative material to ensure the insulation state between metal plate 60 and bus bars 30. In other words, heat conducting sheet 70 may be a sheet-like thin insulating sheet including an insulative material. Heat conducting sheet 70 is a resin sheet including a resin material. In the present embodiment, heat conducting sheet 70 includes a resin material that is electrically insulating. As one example, as the resin material included in heat conducting sheet 70, a silicone or acrylic resin material can be used.

Preferably, heat conducting sheet 70 includes an elastomer having high thermal conductivity and high rubber elasticity, for example. Thereby, heat conducting sheet 70 elastically deforms because it is held by lower case 12 and metal plate 60, and thus heat conducting sheet 70 can be brought into close contact with lower case 12 and metal plate 60.

From the viewpoint of conducting heat of bus bars 30 to metal plate 60 through heat conducting sheet 70, heat conducting sheet 70 preferably has a small thickness. For example, heat conducting sheet 70 preferably has a thickness of 2 mm or less. In the present embodiment, heat conducting sheet 70 has a thickness of 1 mm.

As illustrated in FIG. 5, lower case 12 of case 10 includes bottom plate portion 12c. Bottom plate portion 12c has a first site that is a site overlapping with heat conducting sheet 70, and a second site that is a site not overlapping with heat conducting sheet 70. The thickness of the first site of bottom plate portion 12c overlapping with heat conducting sheet 70 is smaller than that of the second site of bottom plate portion 12c not overlapping with heat conducting sheet 70. As one example, the thickness of the first site of bottom plate portion 12c overlapping with heat conducting sheet 70 is 0.7 mm, and the thickness of the second site of bottom plate portion 12c not overlapping with heat conducting sheet 70 is 1.5 mm.

Thus, by making the thickness of the first site of bottom plate portion 12c overlapping with heat conducting sheet 70 smaller than the thickness of the second site of bottom plate portion 12c not overlapping with heat conducting sheet 70, insulation can be ensured in both case 10 and heat conducting sheet 70, and the heat dissipating properties of battery disconnect unit 1 can be improved.

As described above, battery disconnect unit 1 according to the present embodiment includes case 10, the case being a resin case and being electrically insulating, relay 20 disposed in case 10, bus bar 30 connected to terminal 21 of relay 20 and fixed to case 10 by insert molding, metal plate 60, and heat conducting sheet 70 disposed between case 10 and metal plate 60.

Since bus bar 30 is fixed to case 10 that is electrically insulating by insert molding in battery disconnect unit 1 according to the present embodiment as described above, insulation of battery disconnect unit 1 from bus bar 30 in which a large current flows can be easily ensured. In addition, because relay 20 is connected to bus bar 30 fixed by insert molding, mechanical (mechanical) connection strength between relay 20 and bus bar 30 can be ensured. Furthermore, because heat conducting sheet 70 is interposed between case 10 including bus bar 30 (relay bus bar 30a) fixed thereto by insert molding and metal plate 60, heat that conducts to bus bar 30 (relay bus bar 30a) and heat that generates in bus bar 30 can be efficiently conducted to metal plate 60 through heat conducting sheet 70. For example, as represented by the arrow in FIG. 5, the heat of relay 20 that conducts to relay bus bar 30a connected to relay 20 conducts from second plate portion 32 of relay bus bar 30a to first plate portion 31, and further conducts to metal plate 60 through heat conducting sheet 70. Thus, the heat of bus bar 30 (relay bus bar 30a) can be efficiently dissipated.

Accordingly, battery disconnect unit 1 according to the present embodiment can satisfy connection strength between relay 20 and bus bar 30, heat dissipating properties, and insulation properties at the same time.

In particular, in battery disconnect unit 1 according to the present embodiment, heat conducting sheet 70 is in contact with case 10 and metal plate 60.

In such a configuration, heat that conducts to bus bar 30 (relay bus bar 30a) and heat that generates in bus bar 30 can be efficiently conducted to metal plate 60 through heat conducting sheet 70. Thereby, the heat dissipating properties of battery disconnect unit 1 can be further improved.

In battery disconnect unit 1 according to the present embodiment, heat conducting sheet 70 includes a resin material that is electrically insulating.

In this configuration, not only case 10 including an insulation material that is electrically insulating but also heat conducting sheet 70 that is electrically insulating are interposed between bus bar 30 (relay bus bar 30a) and metal plate 60. Thus, compared to the case where heat conducting sheet 70 includes a conductive material, insulation of battery disconnect unit 1 can be further ensured.

Although a structure in which heat conducting sheet 70 and metal plate 60 are insert formed inside case 10 (lower case 12) can also be considered, this structure has problems described below.

As a first problem, heat conducting sheet 70 cannot be disposed only around bus bar 30 (relay bus bar 30a) during insert molding, which limits the shape of heat conducting sheet 70, reducing the heat dissipating properties of battery disconnect unit 1.

As a second problem, when heat conducting sheet 70 is bonded to metal plate 60, followed by insert molding, heat conducting sheet 70 degrades because the heat-resistant temperature (about 130 degrees) of heat conducting sheet 70 is lower than the temperature of case 10 (lower case 12) (resin temperature: about 300 degrees) during insert molding.

In contrast, because heat conducting sheet 70 is disposed to the outside of case 10 (lower case 12) in battery disconnect unit 1 according to the present embodiment, the shapes of heat conducting sheet 70 and metal plate 60 can be freely set. Battery disconnect unit 1 according to the present embodiment has a structure in which heat conducting sheet 70 and metal plate 60 are bonded directly (disposed externally) below case 10 but not insert formed inside case 10 (lower case 12). Thus, battery disconnect unit 1 according to according to the present embodiment never causes the above-mentioned first and second problems, and can implement a size reduction in battery disconnect unit 1 by giving insulation properties by both of heat conducting sheet 70 and case 10.

Furthermore, in battery disconnect unit 1 according to the present embodiment, metal plate 60 is in an electrically floating state.

In such a configuration, insulation of battery disconnect unit 1 can be further ensured.

In battery disconnect unit 1 according to the present embodiment, metal plate 60 is an aluminum plate including a metal material containing aluminum as the main component.

Since such a configuration enables heat of bus bar 30 (relay bus bar 30a) to efficiently conduct to metal plate 60 through heat conducting sheet 70, the heat dissipating properties of battery disconnect unit 1 can be further improved.

In battery disconnect unit 1 according to the present embodiment, metal plate 60 is a bottom plate of battery disconnect unit 1, and a surface of metal plate 60 opposite a surface facing heat conducting sheet 70 is exposed.

In such a configuration, heat of bus bar 30 (relay bus bar 30a) that conducts to metal plate 60 can be efficiently dissipated to the air. Thereby, the heat dissipating properties of battery disconnect unit 1 can be further improved.

In battery disconnect unit 1 according to the present embodiment, bottom plate portion 12c in case 10 includes a first site that is a site overlapping with heat conducting sheet 70, and a second site that is a site not overlapping with heat conducting sheet 70, and the first site has a thickness smaller than a thickness of the second site.

The resin material for forming case 10 has thermal conductivity lower than that of a metal material. Thus, by the thickness of the first site of bottom plate portion 12c in case 10 overlapping with heat conducting sheet 70 smaller, heat of bus bar 30 (relay bus bar 30a) can be efficiently conducted to heat conducting sheet 70. By increasing the thickness of the second site of bottom plate portion 12c in case 10 not overlapping with heat conducting sheet 70, the mechanical strength of case 10 to which bus bar 30 is fixed can be ensured. Thereby, the connection strength between relay 20 and bus bar 30, the heat dissipating properties, and the insulation can be further satisfied at the same time.

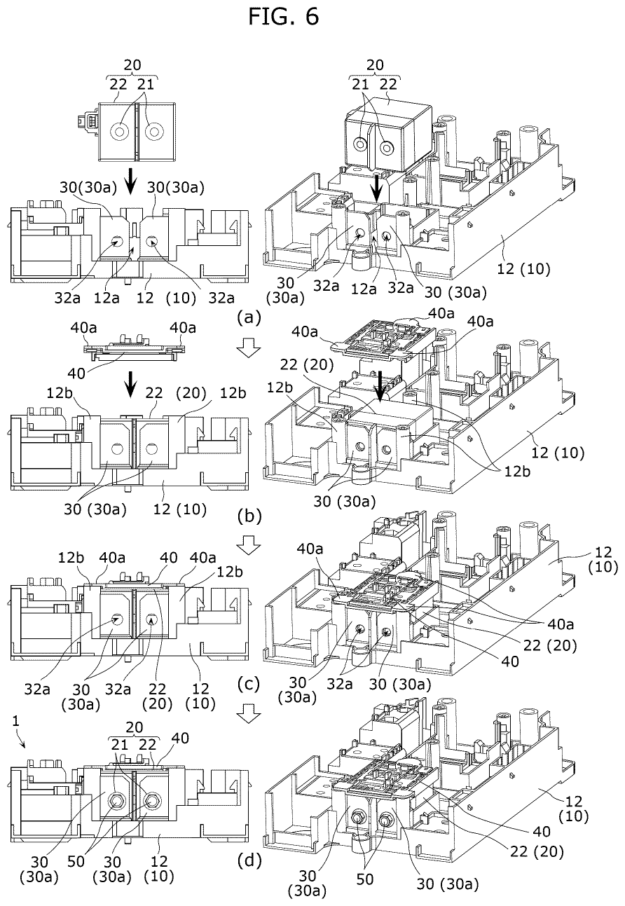

Next, the method for producing battery disconnect unit 1 according to the present embodiment will be described with reference to FIG. 6. FIG. 6 is a diagram for illustrating a method for producing battery disconnect unit 1 according to the embodiment. In (a) to (d) of FIG. 6, the diagrams in left are side views, and those in right are perspective views. FIG. 6 illustrates a configuration of only part of the components constituting battery disconnect unit 1. For example, for relay 20, only one of two relays 20 is illustrated, and for bus bar 30, only relay bus bar 30a is illustrated.

As illustrated in (a) of FIG. 6, first, relay 20 is disposed in case 10 to which bus bar 30 is fixed. Specifically, relays 20 are arranged in lower case 12 to which a plurality of bus bars 30 including relay bus bar 30a are fixed by insert molding. At this time, relay housing 22 of relay 20 is disposed in relay accommodation portion 12a of lower case 12 to align terminal 21 of relay 20 with insertion hole 32a of relay bus bar 30a.

Next, as illustrated in (b) of FIG. 6, relay cover 40 is disposed above relay 20 disposed in case 10. Specifically, relay cover 40 is placed above supports 12b of lower case 12 to cover relay housing 22 of relay 20 disposed in lower case 12. At this time, relay cover 40 is placed above supports 12b to locate attachments 40a of relay cover 40 above supports 12b of lower case 12. When relay cover 40 is placed above supports 12b, relay cover 40 and relay housing 22 of relay 20 may be in contact with each other, and may not be in contact with each other.

Next, as illustrated in (c) of FIG. 6, relay cover 40 is fixed to case 10 in the state where relay cover 40 is pressed against case 10. Specifically, attachments 40a of relay cover 40 are bonded to supports 12b of lower case 12 while relay cover 40 is being pressed down from above.

For example, by placing a pressing member (not illustrated) above relay cover 40 and pressing the pressing member against relay cover 40 with a pressurizing machine, attachments 40a of relay cover 40 are bonded to supports 12b of lower case 12 while pressure is being applied to relay cover 40. Attachments 40a of relay cover 40 are bonded to supports 12b of lower case 12, for example, by ultrasonic, thermal, or laser welding. In other words, attachments 40a of relay cover 40 are bonded to supports 12b of lower case 12 by melting the resin forming relay cover 40 and the resin forming lower case 12 by applying ultrasonic vibration to attachments 40a of relay cover 40 or irradiating attachments 40a with laser light.

At this time, when relay cover 40 is placed above supports 12b (step in (b) of FIG. 6) and relay cover 40 is not in contact with relay housing 22 of relay 20, relay cover 40 is brought into contact with relay housing 22 to press relay housing 22 against lower case 12 by bonding relay cover 40 to supports 12b of lower case 12 while pressure is being applied to relay cover 40.

Thus, by bonding relay cover 40 to lower case 12 while pressure is being applied to relay cover 40, relay 20 can be held by lower case 12 in a state where relay 20 is pressed against lower case 12 by relay cover 40. Even when relay 20 is disposed in lower case 12 to be tilted in the step in (a) of FIG. 6, relay cover 40 is flexibly bonded to lower case 12 by bonding relay cover 40 to lower case 12 while pressure is being applied to relay cover 40. As a result, relay cover 40 allows relay 20 to be held in lower case 12 without causing stress in relay 20. Thus, relay 20 can be stably fixed to lower case 12 without directly fixing relay 20 to lower case 12.

Next, as illustrated in (d) of FIG. 6, after relay cover 40 is fixed to case 10, terminal 21 of relay 20 is fixed to bus bar 30 with screw 50. Specifically, screw 50 is inserted through insertion hole 32a of relay bus bar 30a, and screwed into terminal 21 of relay 20. Thereby, relay bus bar 30a and relay 20 can be electrically and mechanically fixed. At this time, terminal 21 of relay 20 is not covered by relay cover 40 in the insertion direction of screw 50. Thereby, even after relay 20 is covered by relay cover 40, relay 20 and relay bus bar 30a can be easily fixed with screw 50.

Here, features of the method for producing battery disconnect unit 1 according to the present embodiment will be described compared to battery disconnect unit 1X according to Comparative Example with reference to FIG. 7. FIG. 7 is a diagram illustrating the configuration of battery disconnect unit 1X according to Comparative Example.

As illustrated in FIG. 7, battery disconnect unit 1X includes case 10X including a resin, and relay 20X and bus bar 30X accommodated in case 10X.

In battery disconnect unit 1X illustrated in FIG. 7, relay 20X is fixed to case 10X. In this case, a bolt as screw 51X is inserted into a fixing attachment (collar) disposed on a lateral surface of relay housing 22X of relay 20X, and screw 51X is screwed into nut 35X embedded in case 10X. Thereby, relay housing 22X of relay 20X can be fixed to case 10X. After relay 20X is fixed to case 10X, by screwing bus bar 30X as relay bus bar 30a to terminal 21X of relay 20X with screw 52X and screwing relay 20X case 10X with screw 53X, relay 20X and relay bus bar 30a can be electrically and mechanically connected and relay bus bar 30a can be fixed to case 10X. In FIG. 7, when bus bar 30X as relay bus bar 30a is fixed to case 10X with screw 53X, upper bus bar 30b as upper bus bar 30X is overlaid on relay bus bar 30a, and upper bus bar 30b and relay bus bar 30a are fastened together with screw 53X.

In battery disconnect unit 1X illustrated in FIG. 7, case 10X including a resin unintentionally distorts or deforms as illustrated in FIG. 7. When relay 20X is disposed in case 10X which deforms as illustrated, relay 20X is fixed to case 10X in a state where relay 20X is tilted. When case 10X does not deform, relay 20X may be tilted during assembly, and may be fixed to case 10X in the state where relay 20X is tilted. Thus, battery disconnect unit 1X in the related art, a failure may occur in assembly of relay 20X.

When a failure occurs in assembly of relay 20X, bus bar 30X (relay bus bar 30a) connected to relay 20X is screwed into terminal 21X of relay 20X or fixed to case 10X in a state where bus bar 30X is tilted. Furthermore, as a result of tilt of relay bus bar 30a, upper bus bar 30b fastened together to relay bus bar 30a is also connected to relay bus bar 30a in a state where upper bus bas 30b is tilted. Thus, in battery disconnect unit 1X in the related art, a failure may occur in assembly of bus bar 30X (relay bus bar 30a).

When a failure occurs in assembly of relay bus bar 30a as described above, relay bus bar 30a is not in surface contact with terminal 21X of relay 20X and/or upper bus bar 30b. In other words, when a failure occurs in assembly of relay bus bar 30a to tilt relay bus bar 30a, relay bus bar 30a is connected to terminal 21X of relay 20X with line contact or point contact, or relay bus bar 30a is connected to upper bus bar 30b with line contact or point contact. For this reason, although electricity conducts, the resistance value may increase in a connection portion in relay bus bar 30a with terminal 21X of relay 20X and/or upper bus bar 30b, and the connection portion may become a heat generating source. Alternatively, in the connection portion in relay bus bar 30a with terminal 21X of relay 20X and/or upper bus bar 30b, a gap may be formed between the contact surface of relay bus bar 30a and the contact surface of terminal 21X of relay 20X and/or the contact surface of upper bus bar 30b, and corrosion may be accelerated in this connection portion.

In particular, when bus bar 30X (relay bus bar 30a) including copper has a thickness of 2 mm or less, a fastening force to screw relay bus bar 30a with screws 51X and 52X forces relay bus bar 30a to distort and deform. This may result in surface contact of bus bar 30X with terminal 21X of relay 20X and/or upper bus bar 30b in some cases. When bus bar 30X (relay bus bar 30a) including copper has a thickness of more than 2 mm (e.g., 3 mm or more), bus bar 30X does not deform by the fastening force from the screws, and the failure in assembly of relay bus bar 30a is left as illustrated in FIG. 7. In battery electric vehicles in which a larger current flows in bus bar 30X than in hybrid electric vehicles, bus bar 30X that is a thick plate having a thickness of 3 mm or more is used, rather than bus bar 30X that is a thin plate having a thickness of 2 mm or less. Thus, a failure in assembly of bus bar 30X (relay bus bar 30a) is more likely to occur.

Furthermore, when a failure in assembly of relay bus bar 30a occurs and relay bus bar 30a is connected to terminal 21X of relay 20X in a state where relay bus bar 30a is tilted, not only the problems such as heat generation and corrosion as described above occur, but also stress and distortion occur in relay bus bar 30a and/or terminal 21X of relay 20X. When stress and distortion occur in relay bus bar 30a and/or terminal 21X of relay 20X, long-term reliability of battery disconnect unit 1X reduces.

As described above, in the structure of battery disconnect unit 1X illustrated in FIG. 7, when relay 20X and bus bar 30X are fixed to case 10X, relay 20X and bus bar 30X are fixed in a state where these are tilted, resulting in a failure in assembly of relay 20X and bus bar 30X.

In contrast, unlike battery disconnect unit 1X illustrated in FIG. 7 in which relay 20X is fixed to case 10X and then relay 20X and bus bar 30X are fastened, in the method for producing battery disconnect unit 1 according to the present embodiment, as illustrated in FIG. 6, relay 20 is disposed in case 10 to which bus bar 30 is preliminarily fixed, relay 20 is held in case 10 by relay cover 40, and then bus bar 30 and relay 20 are fastened with screw 50. Accordingly, unlike battery disconnect unit 1X illustrated in FIG. 7, a failure in assembly of relay 20 and bus bar 30 does not occur in battery disconnect unit 1 according to the present embodiment.

Battery disconnect unit 1 according to the present embodiment includes relay cover 40 that covers relay 20, and relay cover 40 presses relay 20 against case 10. Furthermore, terminal 21 of relay 20 and bus bar 30 are fixed with screw 50.

In this configuration, as described above, relay 20 can be disposed in case 10 to which bus bar 30 is preliminarily fixed, relay 20 can be fixed to case 10 by relay cover 40, and then bus bar 30 (relay bus bar 30a) and terminal 21 of relay 20 can be fixed with screw 50. Thereby, relay 20 can be held by case 10 without backlash in relay 20, and relay 20 and bus bar 30 (relay bus bar 30a) can be fixed with screw 50 without giving stress to relay 20 and bus bar 30 (relay bus bar 30a). Accordingly, relay 20 and bus bar 30 can be fixed to case 10 without causing a failure in assembly of relay 20 and bus bar 30. For this reason, bus bar 30 (relay bus bar 30a) is in surface contact with terminal 21 of relay 20, and the resistance increases in the connection portion between bus bar 30 (relay bus bar 30a) and terminal 21 of relay 20, preventing heat generation or acceleration of corrosion due to generation of a gap. Since a failure in assembly of relay 20 and bus bar 30 does not occur, relay 20 can be held by case 10 without giving stress to relay 20 and bus bar 30. Thereby, generation of stress and distortion in bus bar 30 (relay bus bar 30a) and terminal 21 of relay 20 can also be prevented. Accordingly, battery disconnect unit 1 having high long-term reliability can be obtained.

In addition, in battery disconnect unit 1 according to the present embodiment, terminal 21 of relay 20 is not covered by relay cover 40 in the insertion direction of screw 50. In other words, terminal 21 of relay 20 is laterally exposed from relay cover 40.

Thereby, even after relay 20 is covered by relay cover 40, relay 20 and relay bus bar 30a can be easily fixed with screw 50.

As described above, bus bar 30 (relay bus bar 30a) is fixed to case 10 by insert molding. Specifically, relay bus bar 30a is fixed to lower case 12 by insert molding.

In this configuration, bus bar 30 (relay bus bar 30a) and case 10 can be preliminarily integrated and fixed, thus eliminating a failure in assembly of bus bar 30. When a nut to which the screw is inserted for retrofitting bus bar 30 to case 10 is fixed to case 10 by insert molding, the nuts and relay bus bar 30a can be fixed to case 10 by insert molding at the same time. In other words, relay bus bar 30a can be fixed to case 10 without adding another insert molding step.

Since stress and distortion do not occur in bus bar 30 (relay bus bar 30a) fixed to case 10 by insert molding, even when relay bus bar 30a fixed by insert molding and another bus bar 30 such as a upper bus bar are fastened with a screw, relay bus bar 30a and another bus bar 30 can be brought in surface contact with each other. In other words, relay bus bar 30a and another bus bar 30 can be connected without generating a gap between relay bus bar 30a and another bus bar 30.

In battery disconnect unit 1 according to the present embodiment, relay bus bar 30a that is bus bar 30 connected to relay 20 includes first plate portion 31, and second plate portion 32 that erects from first plate portion 31. Part or all of first plate portion 31 is embedded in case 10, and second plate portion 32 and terminal 21 of relay 20 are fixed with screw 50.

In this configuration, because second plate portion 32 of bus bar 30 erects from first plate portion 31 to be exposed from case 10, second plate portion 32 of bus bar 30 (relay bus bar 30a) and terminal 21 of relay 20 can be easily fastened with screw 50.

In battery disconnect unit 1 according to the present embodiment, relay 20 includes relay housing 22, and terminal 21 is disposed on a lateral surface of relay housing 22. In other words, relay 20 is disposed to face terminal 21 to a lateral side.

In this configuration, because terminal 21 of relay 20 can be easily caused to face second plate portion 32 that erects from first plate portion 31 of bus bar 30 embedded in case 10, bus bar 30 and terminal 21 of relay 20 can be easily fastened with screw 50.

In battery disconnect unit 1 according to the present embodiment, bus bar 30 (relay bus bar 30a) has a thickness of 3 mm or more. In other words, bus bar 30 has a thickness to prevent deflection even when it is fastened with a screw.

When bus bar 30 deflects due to the fastening force from the screw, bus bar 30 and terminal 21 of relay 20 can be brought into surface contact with each other and fixed because bus bar 30 deflects when bus bar 30 and terminal 21 of relay 20 are fixed with the screw. However, when bus bar 30 does not deflect due to the fastening force from the screw, a failure in assembly of relay 20 and bus bar 30 occurs, and bus bar 30 and terminal 21 of relay 20 cannot be brought into surface contact with each other and fixed. In contrast, in the present embodiment, relay 20 is disposed in case 10 to which bus bar 30 is preliminarily fixed, relay 20 is fixed to case 10 by relay cover 40, and then bus bar 30 (relay bus bar 30a) and relay 20 are fixed with screw 50. Thereby, even when bus bar 30 having a thickness of 3 mm or more (i.e., bus bar 30 that does not deflect due to the fastening force from the screw) is used accompanied by an increase in current, relay 20 and bus bar 30 can be fixed to case 10 without causing a failure in assembly of relay 20 and bus bar 30. Accordingly, battery disconnect unit 1 according to the present embodiment is suitable for battery electric vehicles that need a larger current than that in hybrid electric vehicles.

### Modifications

The technique according to the present disclosure has been described based on the embodiment as above, but the present disclosure is not limited to the above embodiment.

For example, although terminal 21 of relay 20 is disposed on a lateral surface of relay housing 22 in the above embodiment, any other configuration can be used, and terminal 21 of relay 20 may be disposed on a top surface of relay housing 22. In other words, relay 20 may be disposed to face terminal 21 upward, but not to face terminal 21 to a lateral side.

Although relay cover 40 and case 10 are fixed by welding in the above embodiment, any other configuration can be used. For example, relay cover 40 and case 10 may be fixed with a screw or a rivet.

Although in the above embodiment, relay 20 is pressed by relay cover 40 and held by case 10, and then terminal 21 of relay 20 and bus bar 30 are fixed with screw 50, any other method can be used. For example, relay 20 may be pressed by relay cover 40 and held by case 10 by fastening relay 20 disposed in case 10, to which bus bar 30 is fixed, to bus bar 30 with screw 50, and then bonding relay cover 40 to case 10.

Although battery disconnect unit 1 is used in an electric vehicle in the above embodiment, it can be used in any other applications. For example, battery disconnect unit 1 can also be used in electrical products such as home appliances.

Although the technique according to the present disclosure is used in battery disconnect unit 1, it can be used in any other applications. The technique according to the present disclosure may be used in electrical junction boxes other than battery disconnect unit 1. For example, the technique according to the present disclosure may be used in charge units connected to batteries. The technique according to the present disclosure may be used in electrical junction boxes other than units connected to batteries as long as those are electrical junction boxes having a relay.

Besides, the present disclosure also covers embodiments obtained by subjecting the above embodiment to a variety of modifications conceived by persons skilled in the art, and embodiments implemented by any combination of components and functions of embodiments without departing from the gist of the present disclosure. The present disclosure also covers any combination of two or more claims technically noncontradictory among a plurality of claims specified in CLAIMS when the present application is filed. For example, the present disclosure also covers combinations of all the claims included in multi claims or multi-multi claims where dependent form claims specified in CLAIMS when the present application is filed are formed into multi claims or multi-multi claims by referring to all of superordinate claims technically noncontradictory.

### INDUSTRIAL APPLICABILITY

The technique according to the present disclosure can be widely used in a variety of products such as vehicles or electrical products.

### REFERENCE SIGNS LIST

1 battery disconnect unit
2 battery
3 inverter
10 case
11 upper case
12 lower case
12a relay accommodation portion
12b support
12c bottom plate portion
22 relay housing
22a insulating plate
30 bus bar (metal conductor)
31 first plate portion
32 second plate portion
32a insertion hole
30a relay bus bar
40 relay cover
40a attachment
50 screw
60 metal plate
70 heat conducting sheet
100 driving system

1. An electrical junction box comprising:
a case, the case being a resin case and being electrically insulating;
a relay disposed in the case;
a bus bar connected to a terminal of the relay and fixed to the case by insert molding;
a metal plate; and
a heat conducting sheet disposed between the case and the metal plate.

2. The electrical junction box according to claim 1,
wherein the heat conducting sheet is in contact with the case and the metal plate.

3. The electrical junction box according to claim 1, further comprising a relay cover that covers the relay,
wherein the relay cover presses the relay against the case.

4. The electrical junction box according to claim 3,
wherein the terminal of the relay and the bus bar are fixed with a screw.

5. The electrical junction box according to claim 4,
wherein the terminal of the relay is not covered by the relay cover in an insertion direction of the screw.

6. The electrical junction box according to claim 1,
wherein the heat conducting sheet includes a resin material that is electrically insulating.

7. The electrical junction box according to claim 6,
wherein the metal plate is in an electrically floating state.

8. The electrical junction box according to claim 7,
wherein the metal plate is an aluminum plate including a metal material containing aluminum as a main component.

9. The electrical junction box according to claim 1,
wherein the metal plate is a bottom plate of the electrical junction box, and
a surface of the metal plate opposite a surface facing the heat conducting sheet is exposed.

10. The electrical junction box according to claim 1,
wherein a bottom plate portion in the case includes a first site that is a site overlapping with the heat conducting sheet, and a second site that is a site not overlapping with the heat conducting sheet, and
the first site has a thickness smaller than a thickness of the second site.

11. The electrical junction box according to claim 1,
wherein the bus bar includes a surface on which a plating film is formed.

12. The electrical junction box according to claim 1,
wherein the bus bar includes a metal plate or a cast metal conductor.

13. A method for producing an electrical junction box, the method comprising:
disposing a relay in a case to which a bus bar is fixed;
disposing a relay cover above the relay disposed in the case;
fixing the relay cover to the case in a state where the relay cover is pressed against the case; and
fixing a terminal of the relay and the bus bar with a screw after the fixing of the relay cover to the case.

14. The method for producing an electrical junction box according to claim 13, wherein the relay cover is bonded to the case by an ultrasonic wave or welding.
